(19) United States
(12) Patent Application Publication
(10) Pub. No.: US 2025/0258440 A1
(43) Pub. Date: Aug. 14, 2025

(54) METHOD FOR FORMING OVERLAY MARK AND OVERLAY MEASUREMENT METHOD USING THE OVERLAY MARK

(71) Applicant: Samsung Electronics Co..Ltd.:, Suwon-si (KR)

(72) Inventor: Gun Woo PARK, Suwon-si (KR)

(73) Assignee: Samsung Electronics Co., Ltd., Suwon-si (KR)

(21) Appl. No.: 18/941,495

(22) Filed: Nov. 8, 2024

(30) Foreign Application Priority Data
Feb. 14, 2024 (KR) 10-2024-0020875

(51) Int. Cl. G03F 7/00; H10B 12/00

(52) U.S. Cl. CPC G03F 7/70633; G03F 7/70683; H10B 12/01

(57) ABSTRACT

Disclosed are a method for forming an overlay mark with improved reliability and an overlay measurement method using the overlay mark. The method for forming the overlay mark includes forming a lower overlay in a substrate; forming a pattern layer on the substrate; forming an upper overlay on the pattern layer, wherein the upper overlay includes a first area and a second area; forming a material layer on the upper overlay, wherein the material layer includes a third area corresponding to the first area and a fourth area corresponding to the second area; emitting light to the upper overlay through the material layer; and removing a portion of the upper overlay using the light.

### CROSS-REFERENCE TO RELATED APPLICATION

This application claims priority from Korean Patent Application No. 10-2024-0020875, filed on Feb. 14, 2024, in the Korean Intellectual Property Office, the disclosure of which is incorporated by reference herein in its entirety.

### BACKGROUND

### 1. Field

The present disclosure relates to a method for forming an overlay mark and an overlay measurement method using the overlay mark.

### 2. Description of Related Art

In order to meet high performance and increased functionality demanded by consumers, there is a need to increase integration density of a semiconductor memory device. The integration density of a two-dimensional or planar semiconductor memory device corresponds to an area occupied by a unit memory cell, and therefore is greatly affected by a micro-pattern formation skill level. However, because complex equipment is required for pattern miniaturization, the integration density of the 2D semiconductor memory device is increasing, but is still limited. Accordingly, three-dimensional semiconductor memory devices including three-dimensionally arranged memory cells have been proposed.

In a process of manufacturing a 3D semiconductor memory device, an overlay mark may be used to check for misalignment between layers. However, due to the larger number of steps, it is difficult to accurately measure data of a lower overlay mark. Thus, it may be difficult to make accurate inspection of misalignment between layers.

### SUMMARY

One or more embodiments provide an overlay mark with improved reliability.

One or more embodiments provide an overlay measurement method with improved reliability.

Purposes according to the present disclosure are not limited to the above-mentioned purposes. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using features shown in the claims and combinations thereof.

According to an aspect of an embodiment, a method for forming an overlay mark, includes: forming a lower overlay in a substrate; forming a pattern layer on the substrate; forming an upper overlay on the pattern layer, wherein the upper overlay includes a first area and a second area; forming a material layer on the upper overlay, wherein the material layer includes a third area corresponding to the first area and a fourth area corresponding to the second area; emitting light to the upper overlay through the material layer; and removing a portion of the upper overlay using the light.

According to another aspect of an embodiment, a method for forming an overlay mark, includes: forming a lower overlay in a substrate; forming a pattern layer on the substrate; forming an upper overlay on the pattern layer; forming a material layer on the upper overlay, wherein the material layer includes a first area and a second area having different light transmittances; emitting light to the upper overlay through the material layer; and forming a trench in an area of the upper overlay overlapping the second area using the light.

According to another aspect of an embodiment, an overlay measurement method includes: providing a substrate; forming a lower overlay in the substrate; forming a pattern layer on the substrate; forming an upper overlay on the pattern layer; forming a mask layer on the upper overlay; forming a material layer under the mask layer, wherein the material layer includes different a first area and a second area; emitting light to the upper overlay through the material layer; forming a trench in the upper overlay using the light; and measuring a misalignment between the upper overlay and the lower overlay.

According to another aspect of an embodiment, a semiconductor memory device includes: a substrate including: a memory cell area including a first area and a second area; a scribe lane area surrounding the memory cell area; a mold structure on the first area of the substrate and including a plurality of gate electrodes and a plurality of mold insulating films alternately stacked on top of each other; a dummy mold structure on the second area of the substrate and including a plurality of dummy gate electrodes and a plurality of dummy mold insulating films alternately stacked on top of each other; a channel structure extending through the mold structure so as to contact the plurality of gate electrodes; and an overlay mark in the second area of the substrate.

Specific details of embodiments are included below.

### BRIEF DESCRIPTION OF DRAWINGS

The above and other objects, features and advantages will be more apparent from the following description of embodiments, taken in conjunction with the attached drawings, in which:

FIG. 1 is a plan view showing a configuration of a semiconductor memory device before being cut into chips according to some embodiments;

FIG. 2 is an enlarged view of a P area of FIG. 1 according to some embodiments;

FIG. 3 is a plan view for illustrating an overlay mark according to some embodiments;

FIG. 4 is a cross-sectional view cut along a line A1-A1 in FIG. 3 according to some embodiments;

FIG. 5 is a plan view for illustrating an overlay mark according to some embodiments;

FIG. 6 is a cross-sectional view cut along a line A2-A2 in FIG. 5 according to some embodiments;

FIG. 7 is a flowchart for illustrating a method for forming an overlay mark according to some embodiments;

FIG. 8 is an example diagram for illustrating the method for forming the overlay mark in FIG. 7 according to some embodiments;

FIG. 9 is an example diagram for illustrating a related method for forming an overlay mark according to some embodiments;

FIG. 10 is a flowchart for illustrating a method for forming an overlay mark according to some embodiments;

FIG. 11 is an example diagram illustrating the method for forming the overlay mark in FIG. 10 according to some embodiments;

FIG. 12 is an example block diagram for illustrating a semiconductor memory device according to some embodiments;

FIG. 13 is an example circuit diagram for illustrating a semiconductor memory device according to some embodiments;

FIG. 14 is an example cross-sectional view cut along lines B-B and C-C in FIG. 2 according to some embodiments;

FIG. 15 is an enlarged view of a Q area of FIG. 14 according to some embodiments;

FIG. 16 and FIG. 17 are example diagrams for illustrating a semiconductor memory device according to some embodiments;

FIG. 18 is an example block diagram for illustrating an electronic system according to some embodiments;

FIG. 19 is an example perspective view for illustrating an electronic system according to some embodiments; and

FIG. 20 is a schematic cross-sectional view cut along a line I-I in FIG. 19 according to some embodiments.

### DETAILED DESCRIPTIONS

Hereinafter, embodiments will be described with reference to the attached drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

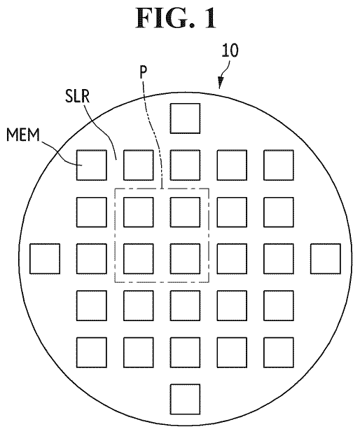

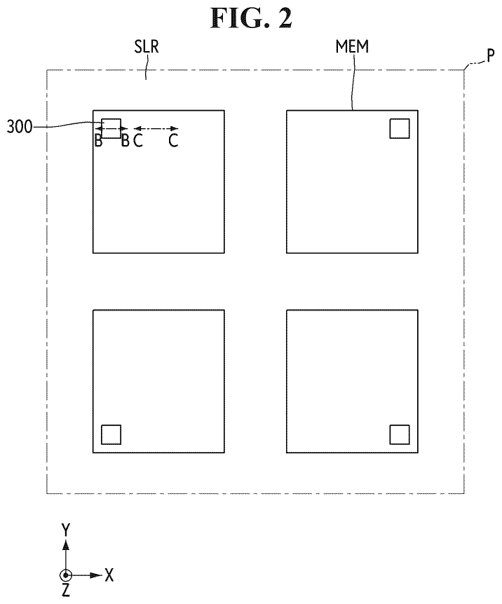

FIG. 1 is a plan view showing a configuration of a semiconductor memory device according to some embodiments before cutting the device into chips. FIG. 2 is an enlarged view of a P area of FIG. 1.

Referring to FIG. 1 and FIG. 2, a semiconductor memory device 10 according to some embodiments before cutting the device into chips may include at least one memory area MEM and a scribe lane area SLR surrounding the memory area MEM. The memory areas MEM may be arranged in a grid while the scribe lane area SLR is disposed therebetween.

The semiconductor memory device 10 according to some embodiments may include a plurality of shot areas, each including at least one memory area MEM and a peripheral area. After being cut into chips, the semiconductor memory device 10 has substantially the same size as that of the shot area. When the semiconductor memory device 10 is cut into chips, the scribe lane area SLR may be partially and/or entirely lost due to dicing.

In some embodiments, the peripheral area may be an area outside the memory area MEM. The peripheral area may include a row decoder (i.e., a row decoder circuit) and a sense amplifier (i.e., a sense amplifier circuit).

In some embodiments, a plurality of memory cells may be arranged in a three-dimensional manner in the memory area MEM. That is, the semiconductor memory device 10 according to some embodiments may be a three-dimensional memory device. Word-lines of the semiconductor memory device 10 may be stacked and have a stacked structure and be connected to the plurality of memory cells, respectively. Furthermore, the word-lines may be drawn out in a stepwise manner and connected to the row decoder, etc.

The row decoder and the sense amplifier may be used during operation of the memory cell. The row decoder may specify a memory cell and control the memory cell to be turned on. The sense amplifier may sense data stored in the memory cell.

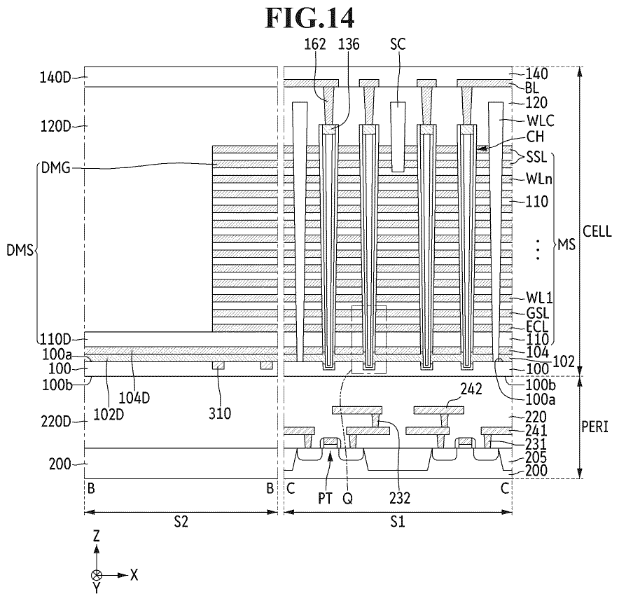

In some embodiments, a plurality of overlay marks 300 may be respectively disposed in the memory areas MEM. The overlay mark 300 may be disposed at one side and/or the other side of the memory area MEM. The overlay mark 300 may be disposed at an edge area of the memory area MEM. The edge area of the memory area MEM may be an area (S2 in FIG. 14) where a dummy mold structure DMS, which will be described later, is disposed.

In FIG. 2, it is shown only that each of the overlay marks 300 is positioned at each of an edge area in −X and +Y directions of an upper and left memory area, an edge area in +X and +Y directions of an upper and right memory area, an edge area in −X and −Y directions of a lower and left memory area, and an edge area in the +X direction and −Y direction of a lower and right memory area. However, the positions of the overlay marks 300 are not limited to what is shown.

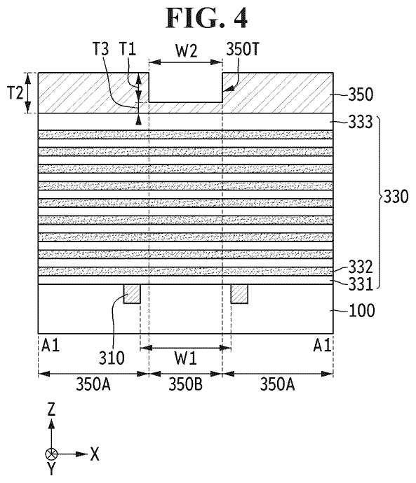

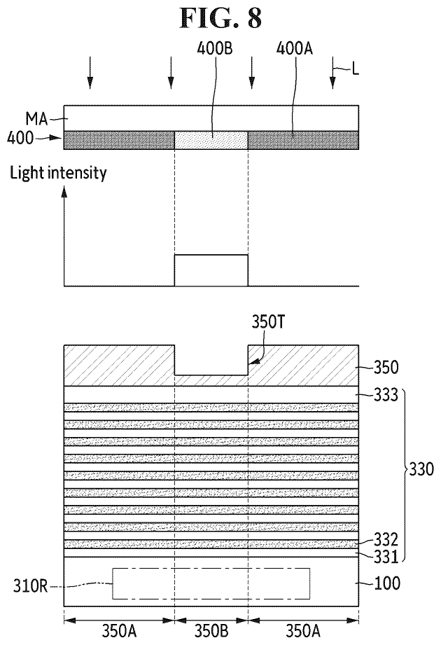

In some embodiments, an amount of light reaching an upper overlay (350 in FIG. 4) may be adjusted using a material layer (400 in FIG. 8) including areas with different light transmittances, thereby forming the upper overlay (350 in FIG. 4) having portions having different thicknesses. Accordingly, in some embodiments, bending due to a large thickness of the upper overlay (350 in FIG. 4) may be prevented such that reliability of an overlay measurement process may be secured compared to a related case. Furthermore, the overlay mark (300 in FIG. 2) according to some embodiments is formed in the memory area MEM, such that the scribe lane area SLR may be secured as much as possible.

In some embodiments, the overlay mark 300 may be used to measure an overlay and inspect a misalignment of a pattern based on the measured overlay. Details related thereto will be described later.

Hereinafter, an overlay mark according to some embodiments is described in detail.

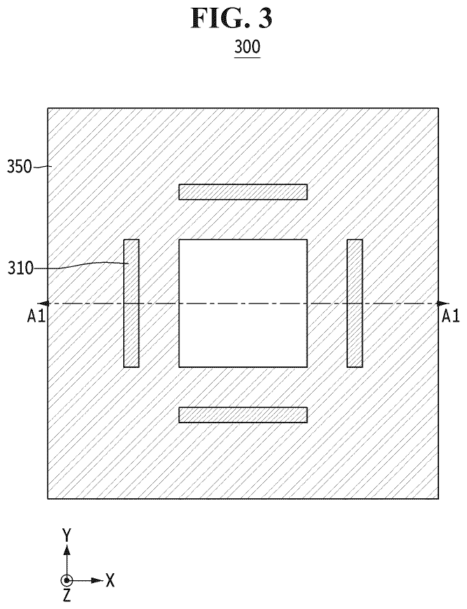

FIG. 3 is a plan view for illustrating an overlay mark according to some embodiments. FIG. 4 is a cross-sectional view cut along a line A1-A1 in FIG. 3.

Referring to FIG. 3 and FIG. 4, the overlay mark 300 according to some embodiments may include a substrate 100, a lower overlay 310, a pattern layer 330, and the upper overlay 350.

The substrate 100 may include, for example, a semiconductor substrate such as a silicon substrate, a germanium substrate, or a silicon-germanium substrate. The substrate 100 may include a silicon-on-insulator (SOI) substrate or a germanium-on-insulator (GOI) substrate. In some embodiments, the substrate 100 may contain impurities. For example, the substrate 100 may contain n-type impurities (e.g., phosphorus (P), arsenic (As), etc.).

The lower overlay 310 may be disposed within the substrate 100. The lower overlay 310 may have a bar shape in a plan view. For example, the lower overlay 310 may include a first portion having a rectangular shape including a long side extending in the first direction X and a short side extending in the second direction Y, and a second portion having a rectangular shape including a long side extending in the second direction Y and a short side extending in the first direction X. The first portions may be spaced apart from each other in the second direction Y, while the second portions may be spaced apart from each other in the first direction X.

In the present disclosure, the first direction X, the second direction Y, and a third direction Z may intersect each other. The first direction X, the second direction Y, and the third direction Z may be substantially perpendicular to each other. The third direction Z may be a thickness direction of the substrate 100.

The lower overlay 310 may be made of a material different from a material of the substrate 100. For example, the lower overlay 310 may include an insulating material film such as a silicon oxide film or a silicon nitride film, or may include a conductive material such as a metal. For example, the lower overlay 310 may be made of a silicon oxide film. However, embodiments are not limited thereto.

The pattern layer 330 may be disposed on the substrate 100. The pattern layer 330 may include a plurality of first insulating layers 331, a plurality of second insulating layers 332, and a third insulating layer 333. The plurality of first insulating layers 331 and the plurality of second insulating layers 332 may be alternately stacked on top of each other. The third insulating layer 333 may constitute a top portion of the pattern layer 330.

In some embodiments, each of the first insulating layer 331 and the third insulating layer 333 may be formed as a silicon oxide film, while the second insulating layer 332 may be formed as a silicon nitride film. However, embodiments are not limited thereto. Furthermore, the pattern layer 330 may be formed as a single layer.

The upper overlay 350 may be disposed on the pattern layer 330. The upper overlay 350 may include different first and second areas 350A and 350B.

The upper overlay 350 may include a trench 350T. For example, the trench 350T may be formed in the upper overlay 350. The trench 350T may include side walls extending in the third direction Z and a bottom surface connecting the side walls to each other. The trench 350T may be recessed by a first depth T1 in the third direction Z.

Due to the trench 350T structure, a thickness T3 in the third direction Z of the second area 350B may be smaller than a thickness T2 in the third direction Z of the first area 350A. In this regard, the upper overlay 350 may extend along a bottom surface of the trench 350T and a portion of an upper surface of the pattern layer 330 may not be exposed through the bottom surface of the trench 350T. The side walls of the trench 350T are shown to extend in parallel to the third direction Z. However, embodiments are not limited thereto. For example, the side walls of the trench 350T may extend in a diagonal direction.

In a plan view, the lower overlay 310 may be formed outwardly of the trench 350T. In this case, a width W2 of the trench 350T may be smaller than a width W1 of the lower overlay 310. However, embodiments are not limited thereto.

In some embodiments, the upper overlay 350 may be a photoresist pattern. However, embodiments are not limited thereto.

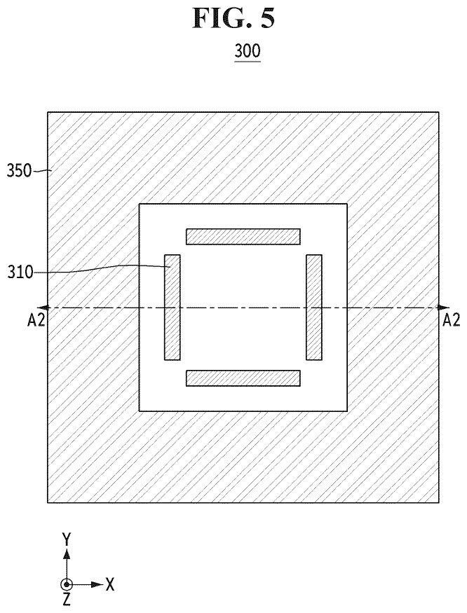

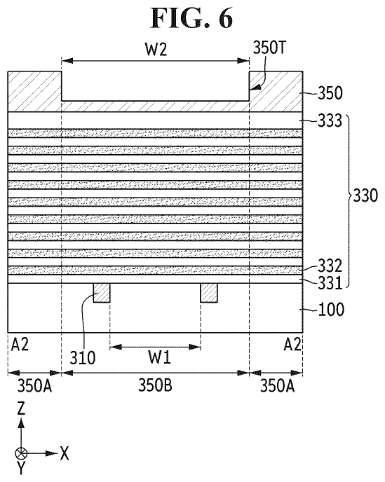

FIG. 5 is a plan view for illustrating an overlay mark according to some embodiments. FIG. 6 is a cross-sectional view cut along a line A2-A2 in FIG. 5. For convenience of description, differences thereof from what has been described above with reference to FIG. 3 and FIG. 4 will be described.

Referring to FIG. 5 and FIG. 6, in a plan view, the lower overlay 310 may overlap the trench 350T along the third direction. In this case, the width W2 of the trench 350T may be larger than the width W1 of the lower overlay 310.

Hereinafter, a method for forming an overlay mark and an overlay measurement method using the overlay mark according to some embodiments will be described.

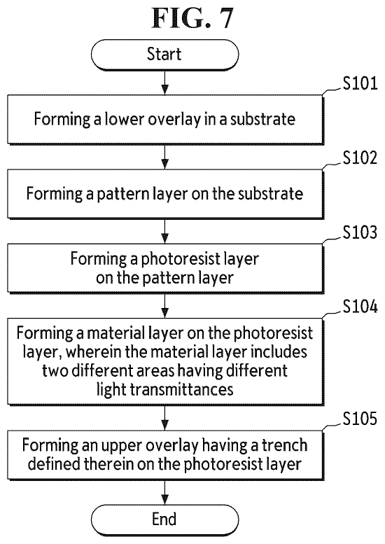

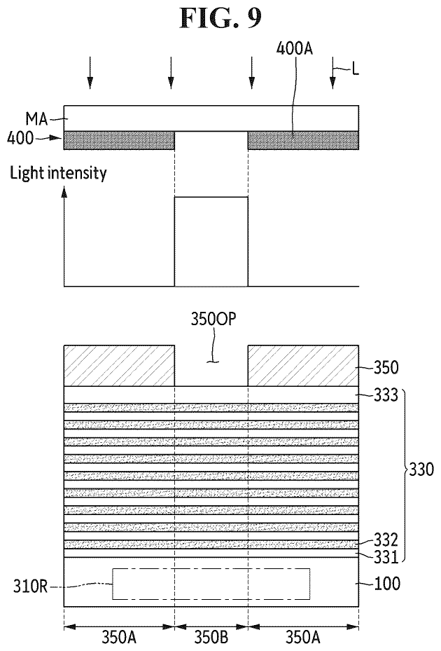

FIG. 7 is a flowchart for illustrating a method for forming an overlay mark according to some embodiments. FIG. 8 is an example diagram for illustrating the method for forming the overlay mark in FIG. 7. FIG. 9 is an example diagram for illustrating a related method for forming an overlay mark. For convenience of descriptions, differences thereof from what has been described above with reference to FIG. 3 to FIG. 6 will be described.

For reference, FIG. 9 is a diagram for illustrating the related method for forming the overlay mark in which an area 400B in FIG. 8 is not formed. Furthermore, a lower overlay area 310R in FIGS. 8 and 9 may indicate an area where the lower overlay (310 in FIG. 4) is positioned.

Referring to FIG. 7 and FIG. 8, the method for forming the overlay mark and the overlay measurement method using the overlay mark may include forming the lower overlay (310 in FIG. 4) in the lower overlay area 310R in the substrate 100 in S101. A portion of the substrate 100 may be etched away to form the lower overlay (310 in FIG. 4).

Subsequently, the pattern layer 330 may be formed on the substrate 100 in S102. First, the first insulating layers 331 and the second insulating layers 332 may be alternately stacked on top of each other, and then the third insulating layer 333 may be formed on the stack thereof.

Next, a photoresist layer may be formed on the pattern layer 330 in S103. The photoresist layer may refer to the upper overlay 350 before the trench 350T, which will be described later, is formed.

Subsequently, the material layer 400 may be formed on the photoresist layer in S104. A mask layer MA may be formed on the photoresist layer. The material layer 400 may be formed under the mask layer MA.

The material layer 400 may include third and fourth areas 400A and 400B overlapping the first and second areas 350A and 350B, respectively, in the third direction (Z in FIG. 4). The third and fourth areas 400A and 400B may have different light L transmittances. The third and fourth areas 400A and 400B may reflect light beams of different wavelength bands from each other, respectively. For example, the third area 400A may include a metal material, and the fourth area 400B may not include the metal material. For example, the fourth area 400B may include a non-metal material.

Subsequently, the trench 350T may be formed in the second area 350B using the material layer 400. Forming the trench 350T may include removing a portion of the upper overlay 350 by adjusting an amount of light reaching the second area 350B.

For example, light L may be emitted to the third and fourth areas 400A and 400B, and an intensity of light L reaching the second area 350B of FIG. 8 may be adjusted to be less than an intensity of light L reaching the second area 350B of FIG. 9. In this regard, the amount of light reaching the second area 350B in FIG. 8 may be adjusted to be less than the amount of light reaching the second area 350B in FIG. 9.

Accordingly, in FIG. 9, the upper overlay 350 corresponding to the second area 350B may be entirely removed to expose a portion of the upper surface of the pattern layer 330 to form an opening 350OP. On the contrary, in FIG. 8, only a portion of the upper overlay 350 may be removed to form the trench 350T.

Accordingly, the upper overlay 350 including the trench 350T may be formed on the pattern layer 330 in S105. The upper overlay 350 may be a photoresist pattern.

A misalignment between the lower overlay 310 and the upper overlay 350 may be checked using the lower overlay 310 and the upper overlay 350 formed in this way. In this regard, the overlay between the lower overlay 310 and the upper overlay 350 may be measured.

In some embodiments, the above process may be repeated at a plurality of positions. The overlay between the lower overlay 310 and the upper overlay 350 may be measured at each of the plurality of positions.

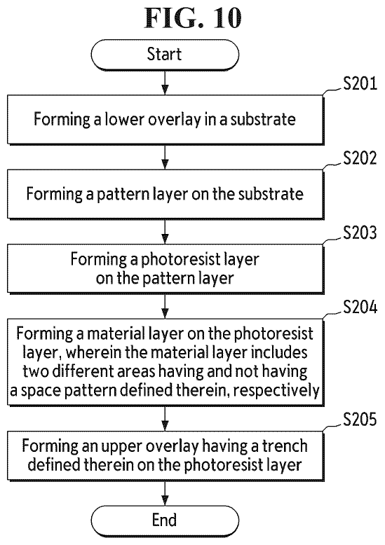

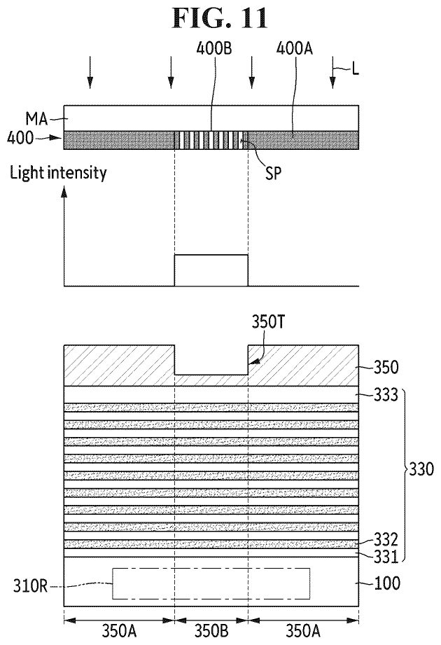

FIG. 10 is a flowchart for illustrating a method for forming an overlay mark according to some embodiments. FIG. 11 is an example diagram for illustrating the method for forming the overlay mark in FIG. 10. For convenience of descriptions, differences thereof from what has been described above with reference to FIG. 3 to FIG. 9 will be described.

The lower overlay area 310R in FIG. 11 may indicate an area where the lower overlay (310 in FIG. 4) is positioned.

Referring to FIG. 10 and FIG. 11, the method for forming the overlay mark and the overlay measurement method using the overlay mark may include forming the lower overlay (310 in FIG. 4) in the lower overlay area 310R in the substrate 100 in S201. A portion of the substrate 100 may be etched to form the lower overlay 310.

Subsequently, the pattern layer 330 may be formed on the substrate 100 in S202. First, the first insulating layers 331 and the second insulating layers 332 may be alternately stacked on top of each other, and then the third insulating layer 333 may be formed on the stack.

Next, a photoresist layer may be formed on the pattern layer 330 in S203. The photoresist layer may refer to the upper overlay 350 before the trench 350T, which will be described later, is formed.

Subsequently, the material layer 400 may be formed on the photoresist layer. The mask layer MA may be formed on the photoresist layer. The material layer 400 may be formed under the mask layer MA.

The material layer 400 may include the third and fourth areas 400A and 400B overlapping the first and second areas 350A, 350B, respectively, in the third direction (Z in FIG. 4). A plurality of space patterns SP including an empty internal space may be formed in the fourth area 400B, while the space pattern SP may not be formed in the third area 400A in S204.

The number of space patterns SP is not limited to what is shown in FIG. 11.

Subsequently, the trench 350T may be formed in the second area 350B using the material layer 400. Forming the trench 350T may include removing a portion of the upper overlay 350 by adjusting an amount of light reaching the second area 350B.

For example, an intensity of light L reaching the second area 350B in FIG. 11 may be adjusted to be less than an intensity of light L reaching the second area 350B in FIG. 9. In this regard, an amount of light reaching the second area 350B in FIG. 11 may be adjusted to be less than an amount of light reaching the second area 350B in FIG. 9.

Accordingly, in FIG. 11, only a portion of the upper overlay 350 corresponding to the second area 350B may be removed to form the trench 350T.

Accordingly, the upper overlay 350 including the trench 350T may be formed on the pattern layer 330 in S205. The upper overlay 350 may be a photoresist pattern.

Accordingly, the overlay between the lower overlay 310 and upper overlay 350 may be measured.

Graphs in FIG. 8, FIG. 9, and FIG. 11 are graphs to show the intensity of light transmitted through varying areas of the upper overlay 350. A horizontal axis of each of the graphs in FIG. 8, FIG. 9, and FIG. 11 may represent an area of the upper overlay 350, and a vertical axis thereof may represent the intensity of light transmitted through the area of the upper overlay 350. A magnitude of the light intensity as shown in each of FIG. 8, FIG. 9, and FIG. 11 is merely an example. Embodiments are not limited to what is shown.

Hereinafter, a semiconductor memory device manufactured using the overlay mark according to some embodiments will be described.

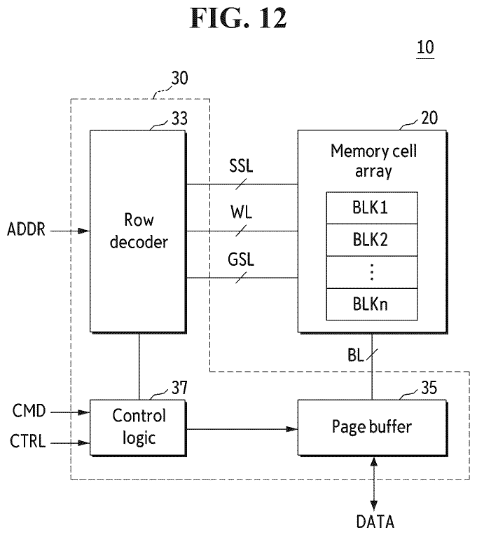

FIG. 12 is an example block diagram for illustrating a semiconductor memory device according to some embodiments.

Referring to FIG. 12, a semiconductor memory device 10 according to some embodiments includes a memory cell array 20 and a peripheral circuit 30.

The memory cell array 20 may include a plurality of memory cell blocks (BLK1 to BLKn). Each of the memory cell blocks BLK1 to BLKn may include a plurality of memory cells. The memory cell array 20 may be connected to the peripheral circuit 30 via a bit-line BL, a word-line WL, at least one string select line SSL, and at least one ground select line GSL. Specifically, the memory cell blocks BLK1 to BLKn may be connected to a row decoder 33 via the word-line WL, the string select line SSL, and the ground select line GSL. Further, the memory cell blocks BLK1 to BLKn may be connected to a page buffer 35 via the bit-line BL.

The peripheral circuit 30 may receive an address ADDR, a command CMD, and a control signal CTRL from an external device to the semiconductor memory device 10, and may transmit and receive data DATA to and from an external device to the semiconductor memory device 10. The peripheral circuit 30 may include a control logic 37, the row decoder 33, and the page buffer 35. The peripheral circuit 30 may further include various sub-circuits such as an input/output circuit, a voltage generation circuit for generating various voltages required for an operation of the semiconductor memory device 10, and an error correction circuit for correcting an error of the data DATA read from the memory cell array 20.

The control logic 37 may be connected to the row decoder 33, the input/output circuit, and the voltage generation circuit. The control logic 37 may control overall operations of the semiconductor memory device 10. The control logic 37 may generate various internal control signals used in the semiconductor memory device 10 in response to the control signal CTRL. For example, the control logic 37 may adjust a voltage level of a voltage supplied to the word-line WL and the bit-line BL when performing a memory operation such as a program operation or an erase operation.

The row decoder 33 may select at least one of the plurality of memory cell blocks BLK1 to BLKn in response to the address ADDR, and may select at least one word-line WL, at least one string select line SSL, and at least one ground select line GSL of the selected at least one memory cell block BLK1 to BLKn. Further, the row decoder 33 may transmit a voltage for performing a memory operation to the word-line WL of the selected at least one memory cell block BLK1 to BLKn.

The page buffer 35 may be connected to the memory cell array 20 via the bit-line BL. The page buffer 35 may operate as a writer driver or a sense amplifier. Specifically, when performing a program operation, the page buffer 35 operates as the writer driver to apply a voltage based on the data DATA to be stored in the memory cell array 20 to the bit-line BL. On the other hand, when performing a read operation, the page buffer 35 may operate as the sense amplifier to detect the data DATA stored in the memory cell array 20.

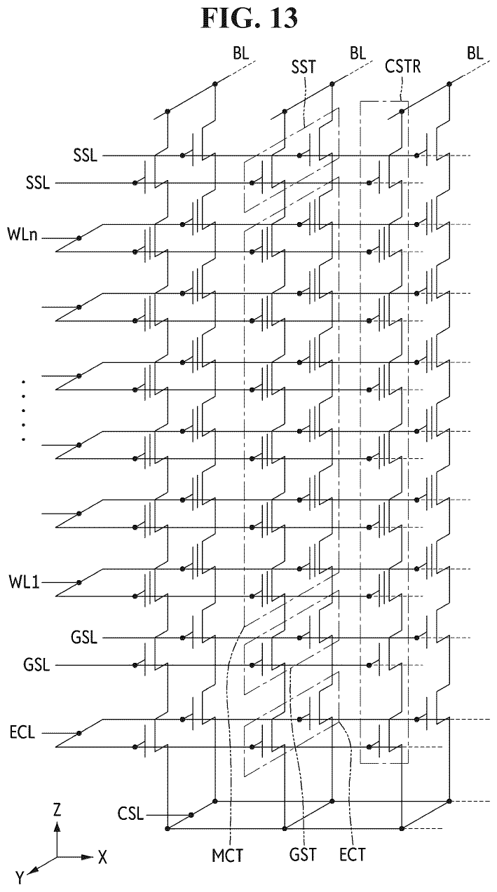

FIG. 13 is an example circuit diagram for illustrating a semiconductor memory device according to some embodiments.

Referring to FIG. 13, a memory cell array (for example, 20 in FIG. 12) of a semiconductor memory device according to some embodiments includes a common source line CSL, a plurality of bit-lines BL, and a plurality of cell strings CSTR.

The common source line CSL may extend in the first direction X. In some embodiments, a plurality of common source line CSLs may be arranged two-dimensionally. For example, the plurality of common source lines CSLs may be spaced apart from each other and each thereof may extend in the first direction X. The same electrical voltage may be applied to the common source lines CSL. Alternatively, different voltages may be applied thereto such that the common source lines CSL may be controlled separately.

The plurality of bit-lines BL may be arranged two-dimensionally. For example, the bit-lines BL may be spaced apart from each other and each thereof may extend in the second direction Y that intersects the first direction X. The plurality of cell strings CSTR may be connected in parallel to each of the bit-lines BL. The cell strings CSTR may be commonly connected to the common source line CSL. That is, the plurality of cell strings CSTR may be disposed between the bit-lines BL and the common source line CSL.

Each cell string CSTR may include a ground select transistor GST connected to the common source line CSL, a string select transistor SST connected to the bit-line BL, and a plurality of memory cell transistors MCT disposed between the ground select transistor GST and the string select transistor SST. Each of the memory cell transistors MCT may include a data storage element. The ground select transistor GST, the string select transistor SST, and the memory cell transistors MCT may be connected in series to each other.

The common source line CSL may be commonly connected to sources of ground select transistors GST. Further, a ground select line GSL, a plurality of word-lines WL1 to WLn and a string select line SSL may be disposed between the common source line CSL and the bit-line BL. The ground select line GSL may act as a gate electrode of the ground select transistor GST, and the word-lines WL1 to WLn may act as gate electrodes of the memory cell transistors MCT, and the string select line SSL may act as a gate electrode of the string select transistor SST.

In some embodiments, an erase control transistor ECT may be disposed between the common source line CSL and the ground select transistor GST. The common source line CSL may be commonly connected to sources of erase control transistors ECT. Further, an erase control line ECL may be disposed between the common source line CSL and the ground select line GSL. The erase control line ECL may act as a gate electrode of the erase control transistor ECT. The erase control transistors ECT may generate gate induced drain leakage (GIDL) to perform an erase operation of the memory cell array.

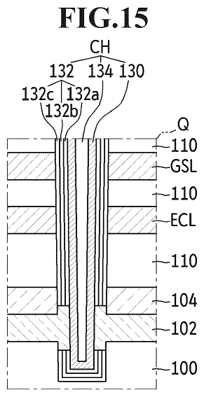

FIG. 14 is an example cross-sectional view cut along lines B-B and C-C in FIG. 2. FIG. 15 is an enlarged view of a Q area of FIG. 14.

Referring to FIG. 14 and FIG. 15, a semiconductor memory device according to some embodiments includes the memory area MEM including first and second areas S1 and S2 and the scribe lane area SLR. The memory area MEM includes a cell structure CELL and a peripheral circuit structure PERI.

The cell structure CELL may include the substrate 100, a mold structure MS, an interlayer insulating layer 120, a channel structure CH, a block isolation area WLC, a bit-line BL, and a first inter-wiring insulating film 140. The substrate 100 may include the memory area MEM and the scribe lane area SLR.

The cell structure CELL may be provided with a memory cell array (for example, 20 in FIG. 12) including a plurality of memory cells. For example, a channel structure CH, a bit-line BL, and gate electrodes ECL, GSL, WL1 to WLn, and SSL, which will be described later, may be disposed in the cell structure CELL. In following descriptions, a surface of the substrate 100 in an area which the memory cell array is disposed, that is, a surface of the first area S1 of the substrate 100 may be referred to as a front surface or side 100a of the substrate 100. Conversely, a surface of the substrate 100 opposite to the front surface of the substrate 100 may be referred to as a back surface or side 100b of the substrate 100.

The mold structure MS may be provided on the front surface 100a of the substrate 100. The mold structure MS may include a plurality of gate electrodes ECL, GSL, WL1 to WLn, and SSL and a plurality of mold insulating films 110 alternately stacked on top of each other while being disposed on the substrate 100. Each of the gate electrodes ECL, GSL, WL1 to WLn, SSL and each of the mold insulating films 110 may extend parallel to the front surface 100a of the substrate 100. The gate electrodes ECL, GSL, WL1 to WLn, and SSL may be sequentially stacked on the substrate 100 while being spaced apart from each other via the mold insulating films 110.

In some embodiments, the gate electrodes ECL, GSL, WL1 to WLn, and SSL may include the erase control line ECL, the ground selection line GSL, and the plurality of word-lines WL1 to WLn that are sequentially stacked on the substrate 100. In further some embodiments, the erase control line ECL may be omitted.

Each of the gate electrodes ECL, GSL, WL1 to WLn, and SSL may include a conductive material, such as a metal such as tungsten (W), cobalt (Co), nickel (Ni), or molybdenum (Mo), or a semiconductor material such as silicon. However, embodiments are not limited thereto. For example, each of the gate electrodes ECL, GSL, WL1 to WLn, and SSL may include tungsten (W) or molybdenum (Mo). Unlike what is shown, each of the gate electrodes ECL, GSL, WL1 to WLn, and SSL may be embodied as a stack of multi films. For example, when each of the gate electrodes ECL, GSL, WL1 to WLn, and SSL is embodied as the stack of multi films, each of the gate electrodes ECL, GSL, WL1 to WLn, and SSL may include a gate electrode barrier film and a gate electrode filling film. For example, the gate electrode barrier film may include titanium nitride (TiN), and the gate electrode filling film may include tungsten (W). However, embodiments are not limited thereto. Preferably, each of the gate electrodes ECL, GSL, WL1 to WLn, and SSL may include tungsten (W).

The mold insulating film 110 may include an insulating material such as at least one of silicon oxide, silicon nitride, and silicon oxynitride. For example, the mold insulating film 110 may include silicon oxide. However, embodiments are not limited thereto.

The interlayer insulating film 120 may be provided on the substrate 100. The interlayer insulating film 120 may cover the mold structure MS. The interlayer insulating film 120 may include an oxide-based insulating material. The interlayer insulating film 120 may include at least one of silicon oxide, silicon oxynitride, and a low-k material with a dielectric constant less than that of silicon oxide. However, embodiments are not limited thereto.

The channel structure CH may be provided within the mold structure MS. The channel structure CH may extend in the vertical direction (hereinafter, the third direction Z) intersecting the front surface 100a of the substrate 100, and may extend through the mold structure MS. For example, the channel structure CH may have a pillar shape (for example, a cylindrical shape) extending in the third direction Z. Accordingly, the channel structure CH may intersect each of the gate electrodes ECL, GSL, WL1 to WLn, and SSL.

The channel structure CH may include a semiconductor pattern 130 and an information storage film 132.

The semiconductor pattern 130 may extend in the third direction Z and extend through the mold structure MS. Although the semiconductor pattern 130 is illustrated only in a shape of a cup, this is only an example. In another example, the semiconductor pattern 130 may have various shapes, such as a cylindrical shape, a rectangular cylindrical shape, and a solid pillar shape. The semiconductor pattern 130 may include, for example, a semiconductor material such as single crystal silicon, polycrystalline silicon, an organic semiconductor material, and a carbon nano structure. However, embodiments are not limited thereto.

The information storage film 132 may be interposed between the semiconductor pattern 130 and each of the gate electrodes ECL, GSL, WL1 to WLn, and SSL. For example, the information storage film 132 may extend along and on an outer face of the semiconductor pattern 130. The information storage film 132 may include, for example, at least one of silicon oxide, silicon nitride, silicon oxynitride, and a high dielectric constant material having a dielectric constant greater than that of silicon oxide. The high dielectric constant material may include, for example, aluminum oxide, hafnium oxide, lanthanum oxide, tantalum oxide, titanium oxide, lanthanum hafnium oxide, lanthanum aluminum oxide, dysprosium scandium oxide, and combinations thereof.

In some embodiments, the information storage film 132 may be composed of a multilayer. For example, as shown in FIG. 15, the information storage film 132 may include a tunnel insulating film 132a, a charge storage film 132b, and a blocking insulating film 132c that are sequentially stacked on an outer face of the semiconductor pattern 130.

The tunnel insulating film 132a may include, for example, silicon oxide or a high dielectric constant material (e.g., aluminum oxide (Al₂O₃), hafnium oxide (HfO₂)) having a dielectric constant higher than that of silicon oxide. The charge storage film 132b may include, for example, silicon nitride. The blocking insulating film 132c may include, for example, silicon oxide or a high dielectric constant material (e.g., aluminum oxide (Al₂O₃), hafnium oxide (HfO₂)) having a dielectric constant higher than that of silicon oxide.

In some embodiments, the channel structure CH may further include a filling pattern 134. The filling pattern 134 may be formed to fill an inside of the cup-shaped semiconductor pattern 130. The filling pattern 134 may include an insulating material, for example, silicon oxide. However, embodiments are not limited thereto.

In some embodiments, the channel structure CH may further include a channel pad 136. The channel pad 136 may be formed to contact the semiconductor pattern 130. For example, the channel pad 136 may be formed within the interlayer insulating layer 120 and contact a top of the semiconductor pattern 130. The channel pad 136 may include, for example, polysilicon doped with impurities. However, embodiments are not limited thereto.

In some embodiments, a source layer 102 and a source support layer 104 may be sequentially formed on the substrate 100 and in the first area S1. The source layer 102 and the source support layer 104 may be interposed between the first area S1 of the substrate 100 and the mold structure MS. For example, the source layer 102 and the source support layer 104 may extend along the front surface 100a of the substrate 100.

In some embodiments, the source layer 102 may be formed to contact the semiconductor pattern 130 of the channel structure CH. For example, as shown in FIG. 15, the source layer 102 may extend through the information storage film 132 and contact the semiconductor pattern 130. This source layer 102 may be provided as a common source line (for example, CSL in FIG. 13) of a semiconductor memory device. The source layer 102 may include, but is not limited to, polysilicon doped with impurities or a metal.

In some embodiments, the channel structure CH may extend through the source layer 102 and the source support layer 104. For example, the channel structure CH may extend through the source layer 102 and the source support layer 104 such that a bottom portion thereof is buried in the substrate 100.

In some embodiments, the source support layer 104 may be used as a support layer to prevent a mold stack from collapsing in a replacement process to form the source layer 102.

A base insulating film may be interposed between the substrate 100 in the memory area MEM and the source layer 102. For example, the base insulating film may include at least one of silicon oxide, silicon nitride, and silicon oxynitride, but is not limited thereto.

The block isolation area WLC may cut the mold structure MS. The mold structure MS may be cut by a plurality of block isolation areas WLC to form a plurality of memory cell blocks (for example, BLK1 to BLKn in FIG. 12). For example, two adjacent block isolation areas WLC may define one memory cell block therebetween. A plurality of channel structures CH may be disposed in each memory cell block defined by the block isolation areas WLC.

In some embodiments, the block isolation area WLC may cut the source layer 102 and the source support layer 104. A lower surface of the block isolation area WLC is shown to be coplanar with a lower surface of the source layer 102. However, this is only an example. In another example, a vertical level of the lower surface of the block isolation area WLC may be lower than a vertical level of the lower surface of the source layer 102.

In some embodiments, the block isolation area WLC may include an insulating material. For example, the insulating material may fill the block isolation area WLC. For example, the insulating material may include at least one of silicon oxide, silicon nitride, and silicon oxynitride, but is not limited thereto.

In some embodiments, a string isolation structure SC may be provided within the mold structure MS. The string isolation structure SC may extend in the first direction X so as to cut the string select line SSL. Each memory cell block defined by the block isolation areas WLC may be divided into a plurality of string areas via the string isolation structure SC. For example, the string isolation structure SC may define two string areas within one memory cell block.

The bit-line BL may be formed on the mold structure MS and the interlayer insulating film 120. The bit-line BL may extend in the second direction Y and intersect the block isolation area WLC. Furthermore, the bit-line BL may extend in the second direction Y and contact the plurality of channel structures CH arranged along the second direction Y. For example, a bit-line contact 162 contacting a top of each of the channel structures CH may be formed within the interlayer insulating film 120. The bit-line BL may be electrically connected to the channel structures CH via the bit-line contact 162.

In some embodiments, the peripheral circuit structure PERI may be disposed on the rear surface 100b of the substrate 100 in the memory area MEM. The peripheral circuit structure PERI may include a peripheral circuit substrate 200 and a peripheral circuit element PT.

The peripheral circuit substrate 200 may be disposed under the substrate 100. For example, an upper surface of the peripheral circuit substrate 200 may face the rear surface 100b of the substrate 100. The peripheral circuit substrate 200 may include, for example, a semiconductor substrate such as a silicon substrate, a germanium substrate, or a silicon-germanium substrate. Alternatively, the peripheral circuit substrate 200 may include silicon-on-insulator (SOI) substrate or a germanium-on-insulator (GOI) substrate.

The peripheral circuit element PT may be formed on the peripheral circuit substrate 200. The peripheral circuit element PT may constitute a peripheral circuit (for example, 30 in FIG. 12) that controls an operation of the semiconductor memory device. For example, the peripheral circuit element PT may include the control logic (such as 37 in FIG. 12), the row decoder (such as ROW in FIG. 1), and the page buffer (such as 35 in FIG. 1). In a following description, a surface of the peripheral circuit substrate 200 on which the peripheral circuit element PT is disposed may be referred to as a front surface of the peripheral circuit substrate 200. On the other hand, a surface of the peripheral circuit substrate 200 opposite to the front surface of the peripheral circuit substrate 200 may be referred to as a back surface of the peripheral circuit substrate 200.

The peripheral circuit element PT may include, for example, a transistor. However, embodiments are not limited thereto. For example, the peripheral circuit element PT may include various active elements such as transistors, as well as various passive elements such as capacitors, resistors, and inductors.

In some embodiments, the rear surface 100b of the substrate 100 may face the front surface of the peripheral circuit substrate 200. For example, a second inter-wiring insulating film 220 covering the peripheral circuit element PT may be formed on the front surface of the peripheral circuit substrate 200. The substrate 100 may be stacked on an upper surface of the second inter-wiring insulating film 220.

A first wiring pattern 241 and 242 contacting the peripheral circuit element PT may be formed in the second inter-wiring insulating film 220. The first wiring patterns 241 and 242 may be connected to each other via a first wiring contact 231 and 232. Furthermore, the first wiring patterns 241 and 242 may be electrically connected to the peripheral circuit element PT via the first wiring contact 231 and 232. Thus, the bit-line BL, each of the gate electrodes ECL, GSL, WL1 to WLn, and SSL, and/or the source layer 102 may be electrically connected to the peripheral circuit element PT.

The peripheral circuit elements PT may be isolated from each other via a peripheral element isolation film 205. For example, the peripheral element isolation film 205 may be provided within the peripheral circuit substrate 200. The peripheral element isolation film 205 may be embodied as a shallow trench isolation (STI) film. The peripheral element isolation film 205 may define an active area of the peripheral circuit elements PT. The peripheral element isolation film 205 may include an insulating material. For example, the peripheral element isolation film 205 may include at least one of silicon nitride, silicon oxide, and silicon oxynitride.

Within the second area S2 of the substrate 100, the lower overlay 310 may be disposed. The lower overlay 310 may be made of a material different from that of the second area S2 of the substrate 100. For example, the lower overlay 310 may be made of a silicon oxide film, but is not limited thereto.

In some embodiments, the lower overlay 310 may include opposing outer and inner walls.

A dummy mold structure DMS may be disposed on the front surface 100a of the second area S2 of the substrate 100. The dummy mold structure DMS may include a plurality of dummy gate electrodes DGE and a plurality of dummy mold insulating films 110D that are alternately stacked on top of each other while being disposed on the second area S2 of the substrate 100.

Each of the dummy gate electrodes DGE and each of the dummy mold insulating films 110D may be layered and have a layered structure extending parallel to the front surface 100a of the second area S2 of the substrate 100. The dummy gate electrodes DGE may be sequentially stacked on the second area S2 of the substrate 100 while being spaced apart from each other via the dummy mold insulating films 110D. Each of the dummy gate electrodes DGE may be made of the same material as that of each of the gate electrodes ECL, GSL, WL1 to WLn, and SSL. The dummy mold insulating films 110D may be made of the same material as that of the mold insulating films 110.

In some embodiments, a dummy source layer 102D and a dummy source support layer 104D may be disposed between the second area S2 of the substrate 100 and the dummy mold structure DMS. For example, the dummy source layer 102D and the dummy source support layer 104D may extend along the front surface 100a of the second area S2 of the substrate 100. The dummy source layer 102D may include, but is not limited to, polysilicon doped with impurities or a metal.

In some embodiments, a dummy interlayer insulating film 120D may be disposed on the dummy mold structure DMS. The dummy interlayer insulating film 120D may cover the dummy mold structure DMS. The dummy interlayer insulating film 120D may include an oxide-based insulating material. The dummy interlayer insulating film 120D may include, but is not limited to, at least one of silicon oxide, silicon oxynitride, and a low-k material with a dielectric constant less than that of silicon oxide.

A dummy first inter-wiring insulating film 140D may be disposed on the dummy interlayer insulating film 120D. The dummy first inter-wiring insulating film 140D may be formed at the same vertical level as that of a portion of the first inter-wiring insulating film 140 in the first area S1.

In some embodiments, a dummy second inter-wiring insulating film 220D may be formed on a portion of the peripheral circuit substrate 200 in the second area S2. The dummy second inter-wiring insulating film 220D may be formed at the same vertical level as that of the second inter-wiring insulating film 220.

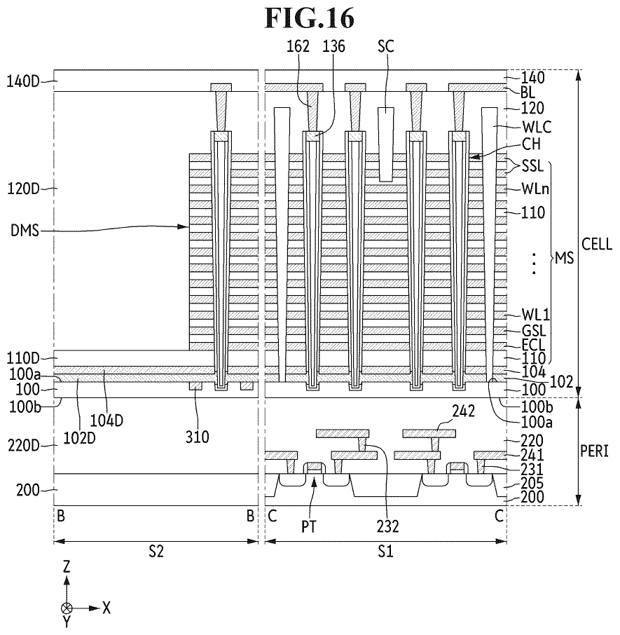

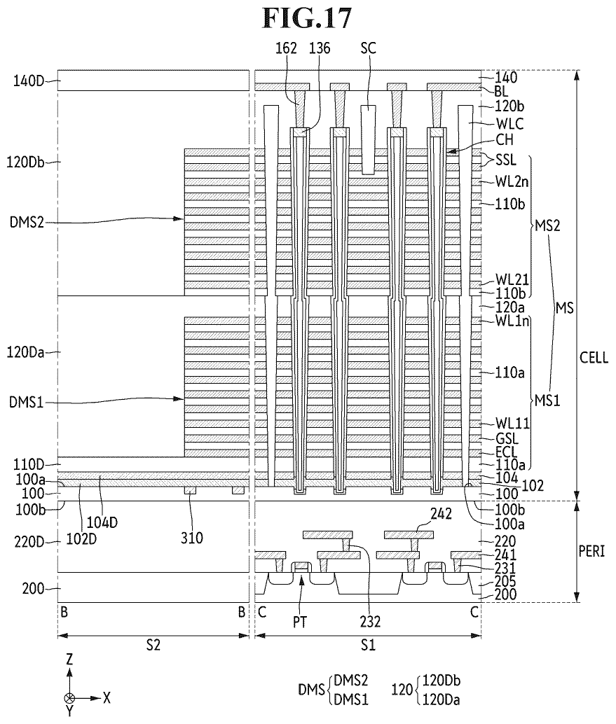

FIG. 16 and FIG. 17 are example diagrams for illustrating semiconductor memory devices according to some embodiments, respectively. For convenience of description, those duplicated with the descriptions as set forth above using FIG. 12 to FIG. 15 are omitted.

Referring to FIG. 16, the semiconductor memory device according to some embodiments may include the channel structure CH disposed in the second area S2. The channel structure CH may be provided within the dummy mold structure DMS. The channel structure CH may extend in the vertical direction (hereinafter, the third direction Z) intersecting the front surface 100a of the substrate 100, and may extend through the dummy mold structure DMS. For example, the channel structure CH may have a pillar shape (for example, a cylindrical shape) extending in the third direction Z. Accordingly, the channel structure CH may intersect each of the gate electrodes ECL, GSL, WL1 to WLn, and SSL.

The descriptions as set forth above with reference to FIG. 12 to FIG. 15 may be similarly applied to the channel structure CH and the bit-line contact 162.

Referring to FIG. 17, the semiconductor memory device according to some embodiments may be a two-stack semiconductor memory device. For example, the mold structure MS may include a lower mold structure MS1 and an upper mold structure MS2. The upper mold structure MS2 may be disposed on the lower mold structure MS1.

The lower mold structure MS1 may include a plurality of lower gate electrodes ECL, GSL, and WL11 to WL1n and a plurality of lower mold insulating films 110a that are alternately stacked on top of each other while being disposed on the first area S1 of the substrate 100. The plurality of lower gate electrodes ECL, GSL, and WL11 to WL1n and the plurality of lower mold insulating films 110a may extend parallel to the front surface 100a of the substrate 100.

The upper mold structure MS2 may include a plurality of upper gate electrodes WL21 to WL2n, and SSL, and a plurality of upper mold insulating films 110b that are alternately stacked on top of each other while being disposed on the lower mold structure MS1. The plurality of upper gate electrodes WL21 to WL2n, and SSL and the plurality of upper mold insulating films 110b may extend parallel to the upper surface of the substrate 100.

In some embodiments, the interlayer insulating film 120 may include a lower interlayer insulating film 120a and an upper interlayer insulating film 120b. The upper interlayer insulating film 120b may be disposed on the lower interlayer insulating film 120a. Each of the lower interlayer insulating film 120a and the upper interlayer insulating film 120b may include, but is not limited to, at least one of, for example, silicon oxide, silicon oxynitride, and a low-k material with a lower dielectric constant than a dielectric constant of silicon oxide.

In some embodiments, the dummy mold structure DMS may include a lower dummy mold structure DMS1 and an upper dummy mold structure DMS2. The upper dummy mold structure DMS2 may be disposed on the lower dummy mold structure DMS1.

The lower dummy mold structure DMS1 may include a plurality of lower dummy gate electrodes and a plurality of lower dummy mold insulating films alternately stacked on top of each other while being disposed on the second area S2 of the substrate 100. The plurality of lower dummy gate electrodes and the plurality of lower dummy mold insulating films may extend parallel to the front surface 100a of the substrate 100.

The upper dummy mold structure DMS2 may include a plurality of upper dummy gate electrodes and a plurality of upper dummy mold insulating films that are alternately stacked on top of each other while being disposed on the lower dummy mold structure DMS1. The plurality of upper dummy gate electrodes and the plurality of upper dummy mold insulating films may extend parallel to the front surface 100a of the substrate 100.

In some embodiments, the dummy interlayer insulating film 120D may include a lower dummy interlayer insulating film 120Da and an upper dummy interlayer insulating film 120Db. The upper dummy interlayer insulating film 120Db may be disposed on the lower dummy interlayer insulating film 120Da. Each of the lower dummy interlayer insulating film 120Da and the upper dummy interlayer insulating film 120Db may include, but is not limited to, at least one of, for example, silicon oxide, silicon oxynitride, and a low-k material with a dielectric constant less than a dielectric constant of silicon oxide.

Hereinafter, with reference to FIG. 12 to FIG. 14 and FIG. 18 to FIG. 20, an electronic system including a semiconductor memory device according to some embodiments is described.

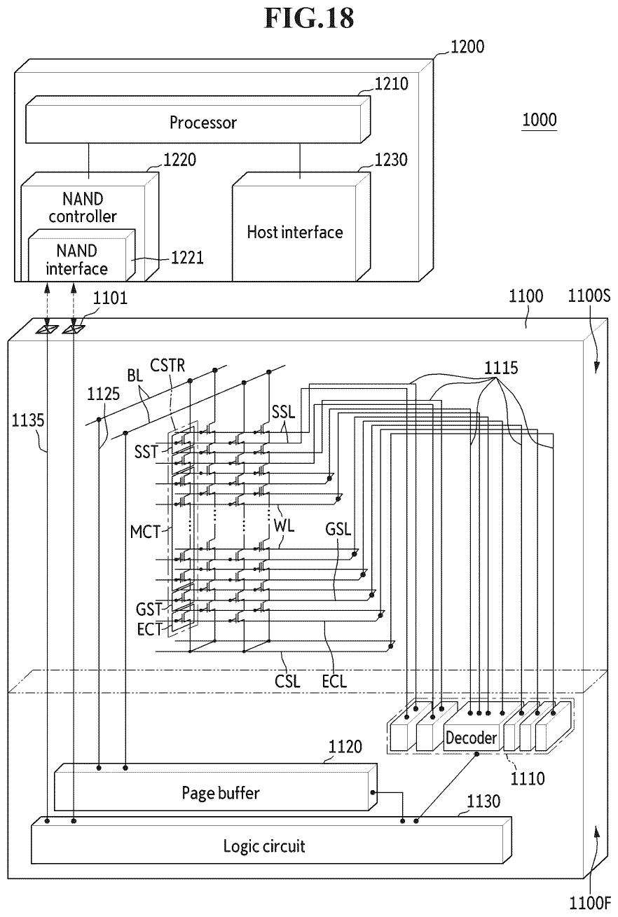

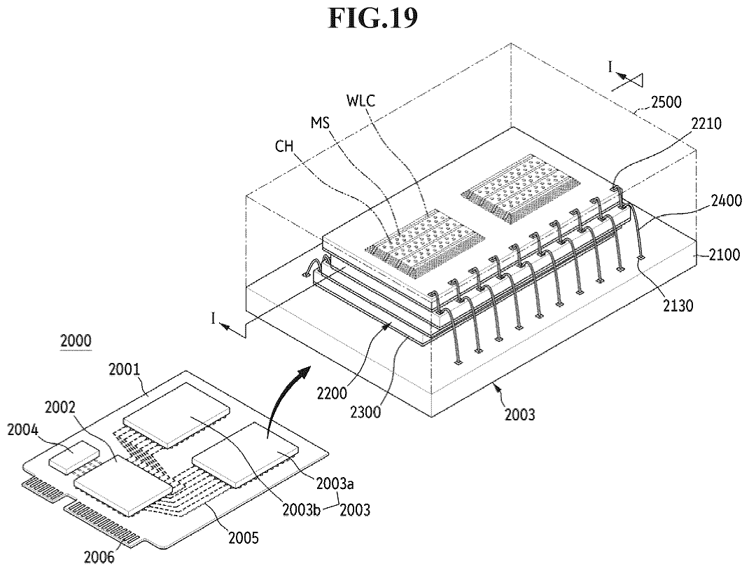

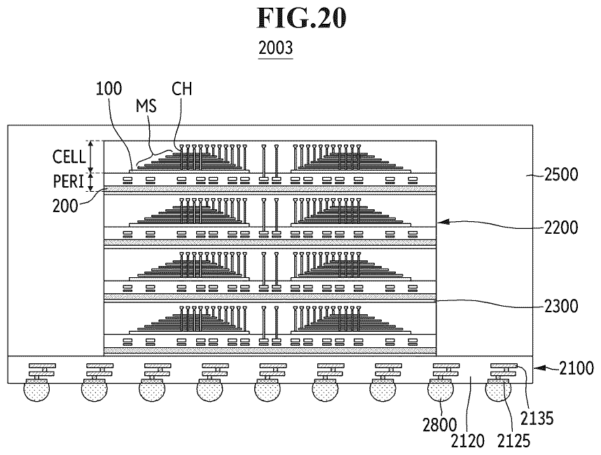

FIG. 18 is an example block diagram for illustrating an electronic system according to some embodiments. FIG. 19 is an example perspective view for illustrating an electronic system according to some embodiments. FIG. 20 is a schematic cross-sectional view taken along a line I-I of FIG. 19. For convenience of illustration, parts duplicate with those as described above with reference to FIGS. 1 to 17 are briefly described or omitted.

Referring to FIG. 18, an electronic system 1000 according to some embodiments may include a semiconductor memory device 1100 and a controller 1200 electrically connected to the semiconductor memory device 1100. The electronic system 1000 may be embodied as a storage device including one or a plurality of semiconductor memory devices 1100 or an electronic device including the storage device. For example, the electronic system 1000 may be embodied as a solid state drive device (SSD), a Universal Serial Bus (USB), a computing system, a medical device, or a communication device including one or a plurality of semiconductor memory devices 1100.

The semiconductor memory device 1100 may be embodied, for example, as a NAND flash memory device, and may include, for example, the semiconductor memory device as described above with reference to FIGS. 12 to 17. The semiconductor memory device 1100 may include a first structure 1100F and a second structure 1100S on the first structure 1100F.

The first structure 1100F may be a peripheral circuit structure including a decoder circuit 1110 (for example, the row decoder 33 in FIG. 12), the page buffer 1120 (for example, the page buffer 35 in FIG. 12), and a logic circuit 1130 (for example, the control logic 37 of FIG. 12).

The second structure 1100S may include the common source line CSL, the plurality of bit-lines BL, and the plurality of cell strings CSTR as described above with reference to FIG. 13. The cell strings CSTR may be connected to the decoder circuit 1110 via the word-line WL, at least one string select line SSL, and at least one ground select line GSL. Further, the cell strings CSTR may be connected to the page buffer 1120 via the bit-lines BL.

In some embodiments, the common source line CSL and the cell strings CSTR may be electrically connected to the decoder circuit 1110 via first connection lines 1115 extending from the first structure 1100F to the second structure 1100S.

In some embodiments, the bit-lines BL may be electrically connected to the page buffer 1120 via second connection lines 1125 extending from the first structure 1100F to the second structure 1100S.

The semiconductor memory device 1100 may communicate with the controller 1200 via an input/output pad 1101 electrically connected to the logic circuit 1130 (e.g., the control logic 37 in FIG. 12). The input/output pad 1101 may be electrically connected to the logic circuit 1130 via an input/output connection line 1135 extending from the first structure 1100F to the second structure 1100S.

The controller 1200 may include a processor 1210, a NAND controller 1220, and a host interface 1230. In some embodiments, the electronic system 1000 may include a plurality of semiconductor memory devices 1100. In this case, the controller 1200 may control the plurality of semiconductor memory devices 1100.

The processor 1210 may control overall operations of the electronic system 1000 including the controller 1200. The processor 1210 may operate based on predefined firmware, and may control the NAND controller 1220 to access the semiconductor memory device 1100. The NAND controller 1220 may include a NAND interface 1221 that processes communication with the semiconductor memory device 1100. Via the NAND interface 1221, a control command for controlling the semiconductor memory device 1100, data to be written to memory cell transistors MCT of the semiconductor memory device 1100, and data to be read from the memory cell transistors MCT of the semiconductor memory device 1100 may be transmitted. The host interface 1230 may provide a communication function between the electronic system 1000 and an external host. Upon receiving a control command from an external host via the host interface 1230, the processor 1210 may control the semiconductor memory device 1100 in response to the control command.

Referring to FIG. 19 and FIG. 20, an electronic system according to some embodiments may include a main substrate 2001, a main controller 2002 mounted on the main substrate 2001, at least one semiconductor package 2003 and at least one DRAM 2004. The semiconductor package 2003 and the DRAM 2004 may be connected to the main controller 2002 via line patterns 2005 formed on the main substrate 2001.

The main substrate 2001 may include a connector 2006 including a plurality of pins coupled to an external host. The number and an arrangement of the plurality of pins in the connector 2006 may vary based on a communication interface between the electronic system 2000 and the external host. In some embodiments, the electronic system 2000 may communicate with the external host using one of interfaces such as Universal Serial Bus (USB), Peripheral Component Interconnect Express (PCI-Express), Serial Advanced Technology Attachment (SATA), M-Phy for Universal Flash Storage (UFS), etc. In some embodiments, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may improve an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a bottom face of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may correspond to the input/output pad 1101 of FIG. 18.

In some embodiments, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In some embodiments, in each of the first semiconductor package 2003a and the second semiconductor package 2003b, the semiconductor chips 2200 may be electrically connected to each other via a connection structure including a through electrode (Through Silicon Via: TSV) instead of the connection structure 2400 using the bonding wire scheme.

In some embodiments, the main controller 2002 and the semiconductor chips 2200 may be included in one package. In some embodiments, the main controller 2002 and the semiconductor chips 2200 may be mounted on a separate interposer substrate different from the main substrate 2001, and the main controller 2002 and the semiconductor chips 2200 may be connected to each other via a line formed in the interposer substrate.

In some embodiments, the package substrate 2100 may be embodied as a printed circuit board. The package substrate 2100 may include a package substrate body 2120, the package upper pads 2130 disposed on a top face of the package substrate body 2120, package lower pads 2125 disposed on a bottom face of the package substrate body 2120, or exposed through the bottom face thereof, and internal lines 2135 disposed in the package substrate body 2120 so as to electrically connect the upper pads 2130 and the lower pads 2125 to each other. The upper pads 2130 may be electrically connected to the connection structures 2400. The lower pads 2125 may be connected to the line patterns 2005 of the main substrate 2001 of the electronic system 2000 as shown in FIG. 19 via conductive connections 2800.

Referring to FIG. 19 and FIG. 20, in the electronic system according to some embodiments, each of the semiconductor chips 2200 may include the semiconductor memory device as described above with reference to FIGS. 12 to 17. For example, each of the semiconductor chips 2200 may include a peripheral circuit structure PERI and a cell structure (CELL) stacked on the peripheral circuit structure PERI. By way of example, the peripheral circuit structure PERI may include the peripheral circuit substrate 200 and the first wiring pattern 241 and 242 as described above using FIGS. 12 to 17. In addition, by way of example, the cell structure CELL may include the substrate 100, the lower overlay 310, the mold structure MS, the channel structure CH, the block isolation area WLC, and the bit-line BL as described above using FIGS. 14 to 17.

In some embodiments, each of the components represented by a block as illustrated in FIGS. 12 and 18 may be implemented as various numbers of hardware and/or firmware structures that execute respective functions described above, according to example embodiments. For example, at least one of these components may include various hardware components including a digital circuit, a programmable or non-programmable logic device or array, an application specific integrated circuit (ASIC), transistors, capacitors, logic gates, or other circuitry using use a direct circuit structure, such as a memory, a processor, a logic circuit, a look-up table, etc., that may execute the respective functions through controls of one or more microprocessors or other control apparatuses. Also, at least one of these components may further include or may be implemented by a processor such as a central processing unit (CPU) that performs the respective functions, a microprocessor, or the like. Functional aspects of example embodiments may be implemented in algorithms that execute on one or more processors. Furthermore, the components, elements, modules or units represented by a block or processing steps may employ any number of related art techniques for electronics configuration, signal processing and/or control, data processing and the like.

While aspects of example embodiments have been particularly shown and described, it will be understood that various changes in form and details may be made therein without departing from the spirit and scope of the following claims.

1. A method for forming an overlay mark, the method comprising:
forming a lower overlay in a substrate;
forming a pattern layer on the substrate;
forming an upper overlay on the pattern layer, wherein the upper overlay comprises a first area and a second area;
forming a material layer on the upper overlay, wherein the material layer comprises a third area corresponding to the first area and a fourth area corresponding to the second area;
emitting light to the upper overlay through the material layer; and
removing a portion of the upper overlay using the light.

2. The method of claim 1, wherein the emitting forms a trench in the first area.

3. The method of claim 2, wherein along a vertical direction, the lower overlay is offset from the trench.

4. The method of claim 3, wherein the trench is narrower than the lower overlay.

5. The method of claim 2, wherein along a vertical direction, the lower overlay overlaps the trench.

6. The method of claim 5, wherein the trench is wider than the lower overlay.

7. The method of claim 1, wherein the first area is thicker than the second area.

8. The method of claim 1, wherein the third area of the material layer comprises a nonmetal material, the fourth area of the material layer comprises a metal material.

9. The method of claim 1, wherein a space pattern defining an empty internal space is formed in the third area, and
wherein the space pattern is absent in the fourth area.

10. A method for forming an overlay mark, the method comprising:
forming a lower overlay in a substrate;
forming a pattern layer on the substrate;
forming an upper overlay on the pattern layer;
forming a material layer on the upper overlay, wherein the material layer comprises a first area and a second area having different light transmittances;
emitting light to the upper overlay through the material layer; and
forming a trench in an area of the upper overlay overlapping the second area using the light.

11. The method of claim 10, wherein the area of the upper overlay overlapping the second area is thinner than an area of the upper overlay overlapping the first area.

12. The method of claim 10, wherein the material layer controls an amount of light reaching the area of the upper overlay overlapping the second area.

13. The method of claim 10, wherein the first area comprises a metal material and the second area comprises a nonmetal material.

14. The method of claim 10, wherein the upper overlay is a photoresist.

15. The method of claim 10, wherein along a vertical direction, the lower overlay is offset from the trench, and
wherein the trench is narrower than the lower overlay.

16. The method of claim 10, wherein along a vertical direction, the lower overlay overlaps the trench, and
wherein the trench is wider than the lower overlay.

17. An overlay measurement method comprising:
providing a substrate;
forming a lower overlay in the substrate;
forming a pattern layer on the substrate;
forming an upper overlay on the pattern layer;
forming a mask layer on the upper overlay;
forming a material layer under the mask layer, wherein the material layer comprises different a first area and a second area;
emitting light to the upper overlay through the material layer;
forming a trench in the upper overlay using the light; and
measuring a misalignment between the upper overlay and the lower overlay.

18. The overlay measurement method of claim 17, wherein the second area comprises a metal material, and the first area comprises a nonmetal material.

19. The overlay measurement method of claim 17, wherein a space pattern defining an empty internal space is formed in the first area, and
wherein the space pattern is absent in the second area.

20. The overlay measurement method of claim 17, wherein the area of the upper overlay overlapping the first area is thinner than an area of the upper overlay overlapping the second area, and
wherein the upper overlay extends along a bottom surface of the trench.

21. (canceled)
